(19) United States
(12) Patent Application Publication
(10) Pub. No.: US 2018/0166603 A1
(43) Pub. Date: Jun. 14, 2018

(54) METHOD OF FABRICATING THIN FILM PHOTOVOLTAIC DEVICES

(71) Applicant: Ramesh Kakkad, Taipei (TW)

(72) Inventor: Ramesh Kakkad, Taipei (TW)

(21) Appl. No.: 15/833,795

(22) Filed: Dec. 6, 2017

Related U.S. Application Data
(60) Provisional application No. 62/431,471, filed on Dec. 8, 2016.

(51) Int. Cl. H01L 31/18; H01L 31/077; H01L 31/0288; H01L 31/0368

(52) U.S. Cl. CPC H01L 31/1872; H01L 31/077; H01L 31/07; H01L 31/0288; H01L 31/03682; H01L 31/182

(57) ABSTRACT

Thin film silicon photovoltaic cell arrangements that include a heavily doped p-type polycrystalline silicon layer spaced-apart from the substrate and bottom electrode in order to reduce grain defects by initiating crystallization at a location far from the substrate. This is accomplished by forming a device structure incorporating such amorphous silicon films on a substrate and annealing at elevated temperature to crystallize the a-Si films such that the crystallization of the a-Si starts within the spaced-apart heavily doped p-type layer and proceeds through the intrinsic silicon layer.

### CLAIM OF PRIORITY

This application claims an invention which was disclosed in Provisional Application No. 62/431,471, filed on Dec. 8, 2016 in the USPTO, entitled “Method of Fabricating Thin Film Photovoltaic Devices”. The benefit under 35 USC § 119(e) of the United States provisional application is hereby claimed, and the aforementioned application is hereby incorporated herein by reference.

### BACKGROUND OF THE INVENTION

### 1. Field of Disclosure

The present invention relates to a method of fabricating polysilicon film as well as devices incorporating such polysilicon film.

### 2. Description of the Related Art

Thin film silicon based solar cells and other devices (such as silicon based thin film transistors, Schottky diodes etc.), are relatively inexpensive and can be made on large areas (such glass substrate) compared to their wafer based counterparts. In the case of thin film silicon solar cell devices, the most popular category is amorphous silicon (a-Si) based thin film solar cells made on large-area glass substrate. Although amorphous silicon based solar cells can be cheaply made on large areas, they have low power conversion efficiency. The amorphous silicon has also instability issues, such as the formation of bond defects when exposed to light, thus the amorphous silicon based solar cell performance decreases with usage.

One way to get around the instability issue is to crystallize all the amorphous silicon layers in such structures. For example, one can crystallize a p-type silicon layer, an intrinsic silicon layer, and an n-type silicon layer that constitute a thin film PIN type of solar cell structure formed on substrate such as glass. The crystallization of amorphous silicon film(s) can be accomplished by annealing the film(s) at elevated temperatures by a process called solid phase crystallization (SPC). The crystallization process not only improves the stability of silicon, but it also improves the power conversion efficiency of solar cells. However, the cost of the high-temperature process step used to crystallize the a-Si films does not adequately justify benefits derived from the improved power conversion efficiency. Thus it is desired to further improve the energy conversion efficiency for such crystalline solar cell structures.

One of the major factors which limit the energy conversion efficiency of thin film polysilicon solar cells as well as performance of other thin film polysilicon devices is the quality of the polysilicon silicon film used in such devices. The SPC crystallized a-Si films have quite a high concentration of grain-boundary and intra-grain defects, which trap charge carriers and cause the solar cell efficiency to be much lower than that for solar cells based on single crystal silicon wafers or ingot silicon. This degrades the performance of other thin film devices formed using such polysilicon films. Even though both grain-boundary defects and intra-grain defect are found in thermally annealed (SPC) polysilicon films, the intra-grain defects seem to dominate the overall defect concentration. The presence of intra-grain defects is known to reduce effective defect-free area down to 30 nm even though polysilicon grain size as determined by locations of grain-boundaries is close to 500 nm for a-Si film crystallized in the practical temperature range of 650-700° C. Thus intra-grain defects seem to dominate the total defect concentration and should be reduced in order to improve the performance of devices employing such polysilicon films.

### SUMMARY OF THE INVENTION

A method of forming a crystalline silicon (polysilicon) thin film on a foreign substrate with a reduced crystalline defect density is provided. This is accomplished by devising a method such that nucleation and crystal growth of precursor a-Si film starts from a surface/interface located away from the substrate surface during the thermal crystallization process. In the conventional crystallization process for a-Si formed on a foreign substrate, the crystallization starts from substrate/a-Si film interface, which is stressed due to difference in thermal expansion co-efficient between the substrate and the a-Si film. The stress during the crystallization causes defect formation in the crystallizing silicon film. The proposed method reduces formation of such defects by changing the location from where the crystallization starts. Further, methods of forming devices incorporating such reduced-defects density polysilicon films are provided.

These and other objects can be achieved by having a photovoltaic cell include a substrate, a transparent electrode arranged on the substrate, a n-type silicon layer arranged on the transparent electrode, an intrinsic silicon layer arranged on the n-type silicon layer and a p-type silicon layer arranged on the intrinsic silicon layer, the p-type silicon layer being doped with boron to a concentration of at least 10²⁰/cm³, wherein the photovoltaic cell is produced by crystallizing a combination of the n-type silicon layer, the intrinsic silicon layer and the p-type silicon layer by annealing at an elevated temperature, wherein the crystallization being initiated within the p-type silicon layer and propagating through the intrinsic silicon layer, the p-type silicon layer being spaced apart from each of the substrate and the transparent electrode by a combination of the n-type silicon layer and the intrinsic silicon layer.

The photovoltaic cell may further include a top electrode arranged on the p-type silicon layer. The elevated annealing temperature may be in the range of 650 to 710° C. A thickness of the intrinsic silicon layer may be in the range of 0.5 to 3 μm and a thickness of the n-type silicon layer may be 20 nm or less. The substrate may be transparent to visible light and include at least one of glass and plastic. An orientation of crystal grain boundaries in each of the silicon layers may approximately be perpendicular to major surfaces of the substrate. Charge carriers within the silicon layers may travel in a direction approximately parallel to crystal grain boundaries. The p-type silicon layer may be doped with boron to a concentration of at least 5×10²⁰/cm³. The photovoltaic cell may also include a top electrode arrangement arranged on the p-type silicon layer, wherein when a combined thickness of the n-type silicon layer, the intrinsic silicon layer and the p-type silicon layer is less than that needed to fully absorb incident radiation, the top electrode arrangement may be designed by either designing the top electrode arrangement to be composed of a non-transparent top electrode that is comprised of a material having a reflectivity of incident radiation of at least 50% at an interface between p-type silicon and the top electrode, or by designing the top electrode arrangement to include a top electrode comprised of a transparent conductive material and a reflective layer arranged on the top electrode having a reflectivity of at least 90%.

According to another aspect of the present invention, there is provided a heterojunction solar cell including a substrate, a SnO₂ layer arranged on the substrate, an intrinsic polycrystalline silicon layer arranged on the SnO₂ layer and a p-type polycrystalline silicon layer arranged on the intrinsic silicon layer, the p-type silicon layer being doped with boron to a concentration of at least 10²⁰/cm³, wherein the heterojunction solar cell may be produced by crystallizing a combination of the intrinsic silicon layer and the p-type silicon layer by annealing at an elevated temperature, wherein the crystallization may be initiated within the p-type silicon layer and then propagating throughout the intrinsic silicon layer, said p-type silicon layer being spaced apart from each of the SnO₂ layer and the substrate by the intrinsic silicon layer.

The heterojunction solar cell may also include a top electrode arranged on the p-type silicon layer, wherein when a combined thickness of the intrinsic silicon layer and the p-type silicon layer is less than that needed to fully absorb incident radiation, the top electrode arrangement may be designed by either designing the top electrode arrangement to be composed of a non-transparent top electrode that is comprised of a material having a reflectivity of incident radiation of at least 50% at an interface between p-type silicon and the top electrode, or by designing the top electrode arrangement to include a top electrode comprised of a transparent conductive material and a reflective layer arranged on the top electrode having a reflectivity of at least 90%, wherein the elevated annealing temperature may be in the range of 650 to 710° C. A thickness of the intrinsic silicon layer may be in the range of 0.5 to 3 μm. The substrate may be transparent to visible light and be comprised of a material selected from glass and plastic. An orientation direction of crystal grain boundaries of each of the silicon layers may approximately be perpendicular to major surfaces of the substrate. Charge carriers within the silicon layers may travel in a direction essentially parallel to the crystal grain boundaries. The p-type silicon layer may be doped with boron to a concentration of at least 5×10²⁰/cm³. Each of the intrinsic and p-type silicon layers may be patterned, wherein the annealing occurs after the intrinsic and p-type silicon layers have been patterned.

According to yet another aspect of the present invention, there is provided a Schottky barrier solar cell including a substrate, a Schottky barrier layer arranged on the substrate, an intrinsic silicon layer arranged on the Schottky barrier layer and a p-type silicon layer arranged on the intrinsic silicon layer, the p-type silicon layer may be doped with boron to a concentration of at least 10²⁰/cm³, wherein the Schottky barrier solar cell may be produced by crystallizing a combination of the intrinsic silicon layer and the p-type silicon layer in a single annealing process at an elevated temperature, wherein the crystallization may be initiated within the p-type silicon layer and progress into the intrinsic silicon layer, the p-type silicon layer may be spaced apart from each of the Schottky barrier layer and the substrate by the intrinsic silicon layer.

### BRIEF DESCRIPTION OF THE DRAWINGS

A more complete appreciation of the invention, and many of the attendant advantages thereof, will be readily apparent as the same becomes better understood by reference to the following detailed description when considered in conjunction with the accompanying drawings, in which like reference symbols indicate the same or similar components, wherein:

FIG. 1A is a perspective diagram showing a technique of fabricating a polysilicon film according to prior art;

FIG. 1B is a perspective diagram showing a technique of fabricating a polysilicon film according to an embodiment of the present invention;

FIG. 2A is Raman spectra for polysilicon film fabricated as per the technique illustrated in FIG. 1A;

FIG. 2B is Raman spectra for polysilicon film fabricated as per the technique illustrated in FIG. 1B;

FIG. 3A is a perspective diagram showing a technique of fabricating a thin film crystalline PIN solar cell according to prior art;

FIG. 3B is a perspective diagram showing a technique of fabricating a thin film crystalline NIP solar cell according to an embodiment of the present invention;

FIG. 3C is a perspective diagram showing a technique of fabricating a thin film crystalline NIP solar cell of FIG. 3B having a modified top electrode arrangement;

FIG. 3D is a perspective diagram showing a technique of fabricating a thin film crystalline NP solar cell according to an embodiment of the present invention; and

FIG. 4 is a perspective diagram showing a technique of fabricating a heterojunction thin film solar cell according to an embodiment of the present invention.

### DETAILED DESCRIPTION OF THE INVENTION

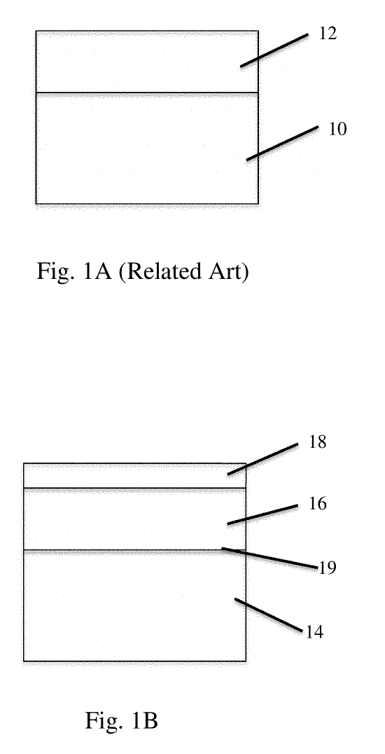

Turning now to FIG. 1A, FIG. 1A illustrates an earlier technique to crystallizing amorphous silicon (i.e. a-Si) arranged on a foreign substrate such as glass. In FIG. 1A, a substrate 10 is provided. A 1500 Å thick intrinsic a-Si film 12 is formed on substrate 10 by plasma enhanced chemical vapor deposition (PECVD). The a-Si film 12 is annealed at an elevated temperature to crystallize the intrinsic a-Si film. A temperature of 700° C. for 5 minutes is needed to fully crystallize the a-Si film 12. In this conventional method, it is known that crystallization starts from the interface 17 between substrate 10 and the intrinsic a-Si film 12 (see Spinella and S. Lombardo, J. Appl. Phys. 84, 5383 1998). During this annealing process, this interface 17 becomes stressed due to thermal coefficient differences between the substrate and the intrinsic silicon film 12. This leads to intra-grain defects (such as dislocation, micro-twins) during nucleation and grain growth (see D. Pribat, P. Legagneux, F. Plais, C. Reita, F. Petinot, and O. Huet, Materials. Research. Society Symposium Proceedings. 424, 127 1996) phases. Thus defects propagate throughout the entire crystallizing film 12 as crystallization propagates from this interface 17 to the rest of film 12.

Referring now to FIG. 1B, FIG. 1B is a perspective diagram showing the technique of fabricating polysilicon according to an embodiment of the present invention. As illustrated in FIG. 1B, a substrate 14 is provided. The substrate 14 in this case is a transparent substrate made of glass. Next an intrinsic a-Si film 16 is formed on the glass substrate 14 by PECVD. The intrinsic a-Si film can be lightly doped, if needed as per device requirement. The thickness of the intrinsic a-Si layer in this case is 1500 Å. Next, a heavily boron-doped amorphous silicon (p-type a-Si) film 18 having a thickness of 500 Å and an impurity concentration of 5×10²⁰/cm³ is formed on top of the intrinsic a-Si film 16. The p-type silicon 18 can be either formed by flowing boron containing gases along with silicon containing gases in a reaction chamber according to PECVD (or other deposition techniques), or can instead be formed by implanting boron only in a top thin part (such as 500 Å) of an intrinsic a-Si film 16. After forming the boron-doped film 18, thermal annealing by rapid thermal annealing (RTA) is carried out. Any atmosphere for annealing, including inert atmospheres such as Argon or Nitrogen can be used.

The thermal annealing budget (i.e., the combination of annealing temperature and annealing duration) required to fully crystallize the entire composite structure of amorphous silicon films 16 and 18 was 670° C. for 5 minutes. Since the heavily boron-doped a-Si film 18 requires lower crystallization thermal budget (for both for nucleation and subsequent crystal growth) compared to the intrinsic a-Si film 12 of FIG. 1A, crystallization is initiated within the boron-doped a-Si film 18 and then propagates into and throughout the intrinsic a-Si film 16. Thus crystallization in the arrangement of FIG. 1B starts from a location away from the strained substrate/intrinsic silicon interface 19.

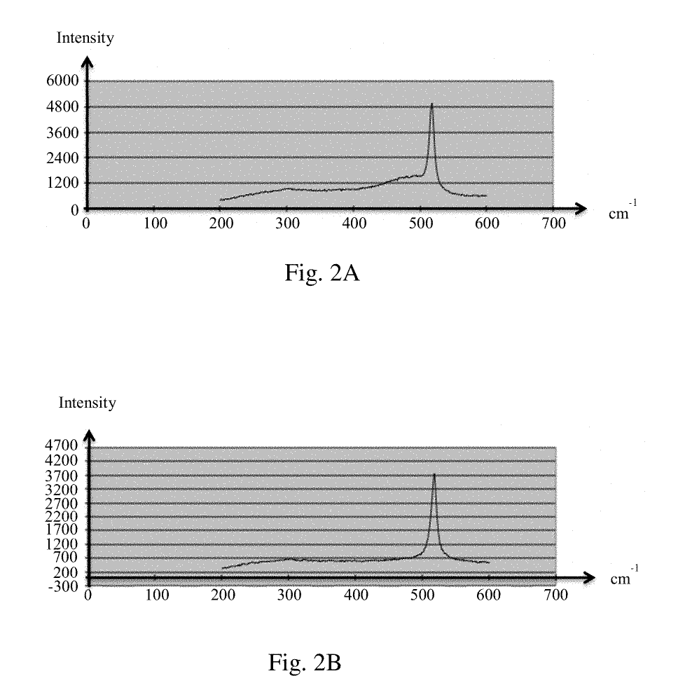

In order to compare the defect density, Raman spectra of the crystallized silicon films formed according to the techniques of FIGS. 1A and 1B were compared as illustrated in FIGS. 2A and 2B respectively. In the Raman spectra of FIG. 2A (corresponding to the conventional method of crystallization according to FIG. 1A), a sharp crystalline silicon peak at 520 cm⁻¹ occurs due to the presence of crystalline silicon. In addition, a broader peak at 480 cm⁻¹ is realized. This broader peak at 480 cm⁻¹ is related to the presence of defects in the crystallized silicon, as defects are akin to amorphous silicon.

In the Raman spectra of FIG. 2B (corresponding to crystallization method according to this invention according to FIG. 1B), we only see a sharp crystalline silicon peak at 520 cm⁻¹, and the broader peak at 480 cm⁻¹ is absent, indicating lower defect-density in these films compared to the conventional method. Since the Raman signal depth is larger than the total silicon film thickness in FIG. 2B, both the silicon films, 16 and 18 of FIG. 1B have the reduced defect density compared to the earlier method of FIG. 1A. After the thermal annealing, the doped crystalline silicon film 18 can be left on the intrinsic crystalline film 16 or it can be removed partially as in a pattern or entirely as per device requirement.

The silicon films crystallized according to the structures illustrated in FIGS. 1A and 1B were also compared by measuring Hall mobility. For preparing the samples for Hall mobility measurements, the heavily boron-doped film 18 was etched off in the structure of FIG. 1B after the crystallization, leaving only the intrinsic polysilicon layer 16. The intrinsic polysilicon layer 12 of FIG. 1A and the intrinsic polysilicon 16 of FIG. 1B were then lightly doped at a boron concentration of 2×10¹⁸ cm⁻³ by ion implantation, slightly above defect density of polysilicon found in traditionally SPC crystallized silicon, which is in the range 10¹⁷ to 10¹⁸ cm⁻³. This is done because when the carrier concentration is close to that of the defect density, effect of defects on carrier motion is easier to detect and measure. The Hall measurement of these films gave hole mobility values of 6 and 15 cm²/V-s for the polysilicon film 12 (crystallized as per the conventional method) and the polysilicon film 16 (crystallized according to the method of this invention), respectively. This increase in mobility for the crystalline silicon film formed according to the technique of this invention shows a reduction in crystal defects, since these defects create potential barriers to carriers, leading to reduced mobility. In the former case (film 12), a larger fraction of available carriers face potential barriers to motion due to defects, resulting in a lower overall Hall mobility value. However in the latter case (film 16) of the present invention, a smaller fraction of the same number of available carriers face potential barriers to motion due to defects, indicating a lower defect density in this case.

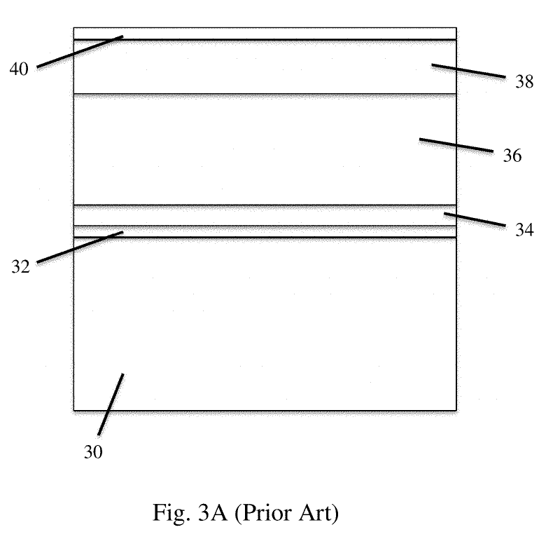

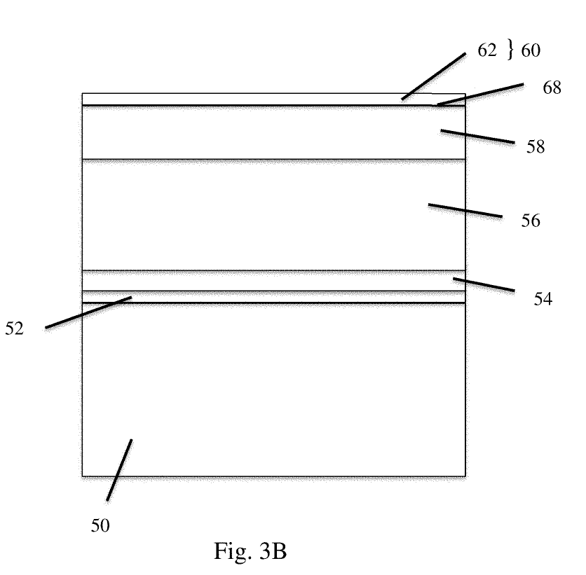

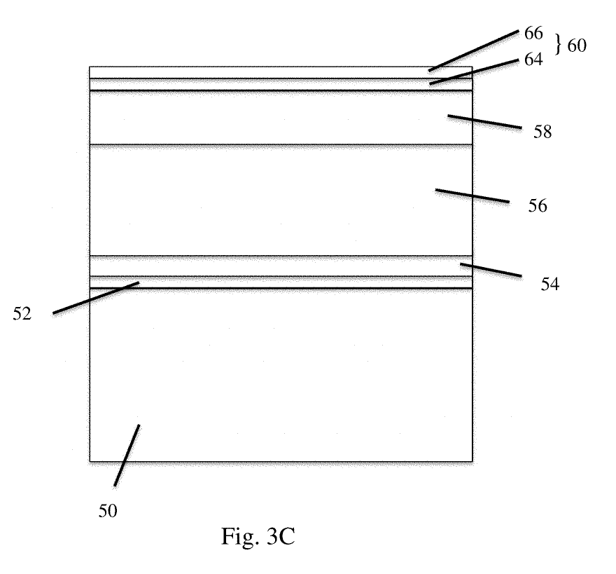

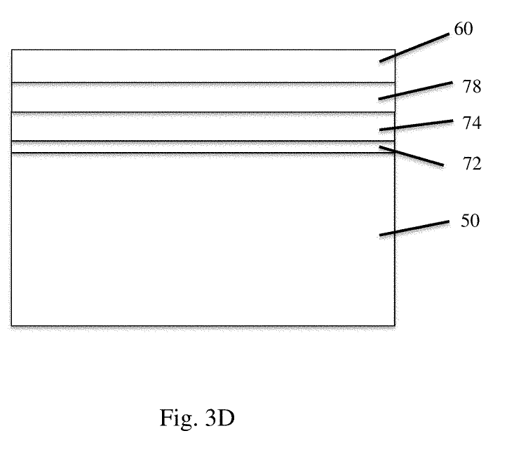

According to another embodiment of the present invention, the crystallization method can be further utilized to form thin film polysilicon solar cell structures. For the case of the solar cell structure illustrated in FIG. 3A from FIG. 6 of U.S. Pat. No. 7,943,447 to Kakkad, the p-type a-Si layer 34 is the bottom layer, the intrinsic a-Si layer 36 is the middle layer and the n-type a-Si layer 38 is the top layer forming a PIN structure. In this structure, the p-type a-Si layer 34 is deposited first (closer to the substrate 30) because it generally leads to better hole-collection efficiency during the operation of the devices. When the PIN silicon structure of FIG. 3A is crystallized, the crystallization starts from the p-type a-Si layer 34 since a boron-doped a-Si film is found to have lower crystallization thermal budget as compared to either of the n-type a-Si film 38 or the intrinsic silicon film 36, Since the p-type a-Si layer 34 is close to the substrate 30 in FIG. 3A and indium tin oxide (ITO) used from electrode layer 32 has a different thermal expansion co-efficient as compared to silicon, the crystallization would start from a high strain region. This is expected to cause defects in a remainder of the crystallizing structure affecting the device performance such as solar cell efficiency.

Turning now to FIGS. 3B and 3C, FIG. 3B is a perspective diagram showing the technique of fabricating a thin film NIP polysilicon solar cell structure on a substrate according to an embodiment of the present invention, and the arrangement of FIG. 3C is similar to that of FIG. 3B but with a differently designed top electrode arrangement 60 to be discussed later. The NIP structure in FIGS. 3B and 3C can also be used as a photo-sensor or a photo-detector devices.

Focusing on the arrangement of FIG. 3B, a transparent substrate such as glass or plastic 50 with a transparent conductor film 52 is provided. The transparent conductor film 52 can be indium tin oxide (ITO), indium zinc oxide (IZO) or other suitable transparent conductor material, which serves as bottom electrode contact for the solar cell structure as well as allowing solar radiation incident from a bottom of substrate 50 to easily pass through to the silicon layers 54, 56 and 58. In the NIP arrangement of FIG. 3B, a n-type a-Si film 54 doped with a donor such as phosphorous and having a thickness of approximately 200 Å or less is formed on top of the bottom electrode layer 52. The n-type a-Si layer 54 is heavily doped with a dopant concentration of higher than 10²⁰/cm³ in order to have a low resistance. An intrinsic a-Si film 56 preferably has a thickness in the range of 0.5 to 3.0 μm and is formed on top of the n-type a-Si film 54. A boron-doped a-Si layer 58 having a thickness of 500 Å or more is formed on top of the intrinsic silicon layer 56. The doping concentration of the boron-doped a-Si layer 58 is generally higher than 10²⁰/cm³.

The device structure of the solar cell of FIG. 3B is denoted as NIP due to the order of deposition of various silicon layers. The NIP structure is thermally annealed by RTA to cause the crystallization of all the silicon layers 54, 56 and 58. Since the crystallization thermal budget for the heavily boron-doped p-type a-Si film 58 is lower than that of either of the intrinsic a-Si layer 56 and n-type a-Si layer 54, the crystallization in this case would start from the p-type a-Si layer 58 and proceed to crystallize a remainder of the NIP structure. Thus, in the arrangement of FIG. 3B, since the crystallization starting point is located further away from substrate 50 as compared to the arrangement of FIG. 3A, the crystallized films will have lower defect densities than that of the arrangement of FIG. 3A. The lower crystalline defect density also increases the diffusion length for holes, thereby improving hole collection efficiency.

A top electrode arrangement 60 of any of FIGS. 3B & 3C may be formed on top of the crystallized p-type silicon film 58 to complete the solar cell device structure. For the case of polysilicon films, a thickness of about 2 μm for the silicon layers is required to nearly fully absorb the incident light for the light wavelength range normally encountered during operation of solar cells. If a total thickness of the silicon layers is less than 2 μm, the top electrode arrangement 60 must be designed so that light that has transmitted all the way through the intrinsic silicon layer 56 can be redirected back into the intrinsic silicon layer 56 for re-absorption by the intrinsic silicon layer 56.

In order to re-direct light back into intrinsic silicon layer 56 when a combined thickness of the silicon layers 54, 56 and 58 is too thin to absorb all the incident light, the top electrode arrangement 60 of the solar cell needs to be designed to reflect light back into silicon layer 58 and 56. A first design for the top electrode arrangement 60 of the solar cell to achieve this goal is illustrated in FIG. 3B and includes in top electrode arrangement 60 a material for the top electrode 62 that is non-transparent by choosing a material for the top electrode 62 so that a reflectivity at the p-type silicon layer 58/top electrode 60 interface 68 is no less than 50%.

A second design for the top electrode arrangement 60 is illustrated in FIG. 3C and includes a transparent conductor for the top electrode 64, and further includes a highly reflective layer 66 over the transparent top electrode 64 to reflect light back into the photovoltaic cell. For example, by using a Al doped ZnO (written as ZnO:Al) transparent electrode 64 with a overlaying reflective layer 66 of Ag, a reflectivity of at least 90% can be achieved for the second design of FIG. 3C. For the reflective layer 66 of FIG. 3C, TiO₂ or white paint can be used instead of Ag in the second design to reduce cost.

For the methods and structures of the embodiments of the present invention, it should be noted that for the boron-doped layer, the higher the impurity doping concentration, the lower the thermal budget is for crystallization. Thus the boron doping concentration should be 10²⁰/cm³ or higher, preferably 5×10²⁰/cm³ or higher.

The p-type a-Si film can be formed either by flowing boron containing gas along with the silicon forming gases in a reaction chamber (such as PECVD chamber), or by first depositing an intrinsic silicon layer (for example by PECVD) followed by ion implantation or ion doping of boron into the silicon layer. Although, the p-type a-Si film formed in a reaction chamber is less expensive than that formed by ion implantation, a clean interface between doped and the intrinsic film is needed in the former case to make sure that crystallization proceeds smoothly to the intrinsic film. This is not an issue when ion implantation is used. Also, in the implanted a-Si film, the dopant peak can be placed within the bulk of the film, thus keeping the crystallization starting location away from any surface impurities or imperfections. It is preferred that deposited silicon layers of the NIP structures in the FIGS. 3B and 3C are formed without breaking the vacuum in order to have clean interface between the various layers.

The crystallization thermal budget is expected to increase upon increasing the thickness of the intrinsic Si layer 56, thus the thermal budget requirement must be balanced with proper intrinsic Si layer 56 thickness required for adequate photo absorption of the incident radiation. Thus it would be preferred to have intrinsic Si layer 56 thickness to be less than 5 μm, and preferably below 3 μm and more preferably in 0.5 to 3 μm range.

The thickness of n-type silicon layer 54 in the arrangement of FIGS. 3B and 3C is preferred to be as thin as possible to allow maximum light to pass through, as it acts as window to solar radiation incident on the intrinsic Si layer 56, thus the n-type Si layer 54 thickness should be preferably 200 Å or below.

Preferably crystallization is carried out at temperatures at or below 680° C., in order to minimize the substrate damage or warping, as many glass substrates used in solar cell industry have strain point near 680° C. Although crystallizing at a temperature below the strain point is ideal, glass bending is found to be acceptable for temperatures up to about 20-30° C. higher than the strain point. Lowering the crystallization temperature below this improves with control of the crystallization process and reduces the glass warping, but must be balanced against an increased time required for crystallization. Thus it is preferred to have the crystallization temperature higher than 650° C.

Also, forming silicon films in patterns instead of large continuous films reduces potential warping of substrate 50 upon crystallization annealing. The crystallization process of the amorphous films can be carried out by furnace annealing, lamp annealing, resistance heating, or a combination of two or more of these techniques. The annealing atmosphere can be any atmosphere, including inert atmospheres such as Argon or Nitrogen.

Additionally, in FIGS. 3B and 3C, the reduced defect-density crystallites in the polysilicon film are expected to grow nearly vertically causing vertical grain boundaries between the crystals. The vertical direction of grain boundaries, especially for the intrinsic Si layer 56 is desirable due to the fact that current in thin film photovoltaic flows in vertical direction, and thus the grain boundaries defects would not impede current flow. Since the polysilicon film also has fewer intra-grain defects that scatter current carriers, it will result in improved device performance.

Turning now to FIG. 3D, FIG. 3D illustrates another solar cell device according to another embodiment of the present invention. In the arrangement of FIG. 3D, the device is an NP solar cell device which is analogous to that of FIGS. 3B and 3C, but with the intrinsic layer 56 removed. Specifically, a transparent conductor 72 is formed on a substrate 50. An n-type silicon layer 74 is formed on transparent conductor 72, a boron-doped silicon layer 78 is formed directly on n-type silicon layer 74, and a top electrode arrangement 60 is formed on p-type silicon layer 78. Either of the top electrode arrangements of FIGS. 3B and 3C can be used for the top electrode arrangement 60 of FIG. 3D. Prior to forming the top electrode arrangement 60, the amorphous silicon layers 74 and 78 are crystallized by annealing. Because boron-doped silicon has a lower annealing temperature than that of n-type silicon, crystallization is initiated at p-type layer 78 and moves down to layer 74 to complete the process.

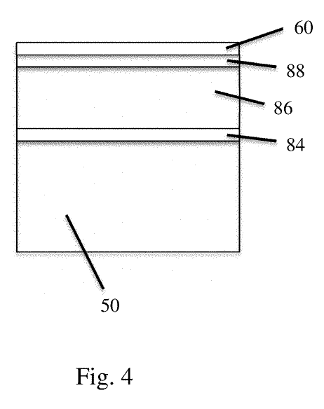

Turning now to FIG. 4, FIG. 4 shows another embodiment of a heterojunction solar cell. On a substrate 50, a SnO₂ layer 84 is deposited. On the SnO₂ layer 84, an intrinsic a-Si layer 86 is deposited. On the intrinsic a-Si layer 86, a heavily p-type doped a-Si layer (i.e. boron-doped) 88 is deposited. The structure is annealed to cause the crystallization of the a-Si layers 86 and 88. Here again the crystallization will start from the p-type a-Si layer 88 rather than the stressed interface between SnO₂ film 84 and the intrinsic a-Si layer 86. This will reduce the defects in the crystallized intrinsic silicon, and thus improve the device performance.

Also illustrated in FIG. 4 is a top electrode arrangement 60 formed on top of p-type a-Si layer 88 to complete the structure of the heterojunction solar cell. This top electrode arrangement 60 may be designed according to that of FIG. 3B where the top electrode arrangement 60 is composed of only a non-transparent top electrode 62 where a reflectivity of incident radiation is at least 50% at the p-type a-Si layer 88/top electrode 62 interface. Alternatively, the top electrode arrangement 60 of FIG. 4 can instead be designed according to that of FIG. 3C where the top electrode arrangement 60 includes both the top electrode 64 comprised of a transparent conductive material like ITO or IZO and a reflective layer 66 sequentially arranged on p-type a-Si layer 88. As in the arrangement of FIG. 3C, the reflective layer 66 should be designed to reflect at least 90% of incident radiation and may be comprised of Ag, TiO₂ or white paint.

In yet another embodiment of the present invention, a Schottky barrier layer can be substituted for the SnO₂ layer 84 of FIG. 4 to form a Schottky barrier solar cell. The Schottky material could be a metal or could be ITO or IZO. A Schottky barrier is a metal-semiconductor interface that produces a potential barrier.

For solar cell, photo detectors or photo-sensor applications of NIP or NP junction structures, the light is generally incident from the substrate side. Another possibility is that the light is incident from the opposite side (from the p-type silicon layer side). In that case, the substrate and the bottom conductor layer need not be transparent and a ceramic or metal substrate can be used. If metal substrate is used, it could also act as an electrode layer.

The above discussed thin film crystalline silicon solar cell structures can be used alone or in tandem with other structures, for example crystalline silicon/amorphous silicon tandem structure, where amorphous silicon solar cell structure is formed on top of above crystalline silicon solar cell. Examples include NIP (crystalline)-NIP (amorphous) structure.

While the present invention has been particularly shown and described with reference to exemplary embodiments thereof, it will be understood by those of ordinary skill in the art that various changes in form and details may be made therein without departing from the spirit and scope of the present invention as defined by the following claims. It is therefore desired that the present embodiments be considered in all respects as illustrative and not restrictive, reference being made to the appended claims rather than the foregoing description to indicate the scope of the invention.

What is claimed is:

1. A photovoltaic cell, comprising:
a substrate;
a transparent electrode arranged on the substrate;
a n-type silicon layer arranged on the transparent electrode;
an intrinsic silicon layer arranged on the n-type silicon layer; and
a p-type silicon layer arranged on the intrinsic silicon layer, the p-type silicon layer being doped with boron to a concentration of at least 10²⁰ cm³, wherein the photovoltaic cell is produced by crystallizing a combination of the n-type silicon layer, the intrinsic silicon layer and the p-type silicon layer by annealing at an elevated temperature, wherein the crystallization being initiated within the p-type silicon layer and propagating through the intrinsic silicon layer, the p-type silicon layer being spaced apart from each of the substrate and the transparent electrode by a combination of the n-type silicon layer and the intrinsic silicon layer.

2. The photovoltaic cell of claim 1, wherein the elevated annealing temperature is in the range of 650 to 710° C.

3. The photovoltaic cell of claim 1, wherein a thickness of the intrinsic silicon layer is in the range of 0.5 to 3 μm and a thickness of the n-type silicon layer is 20 nm or less.

4. The photovoltaic cell of claim 1, the substrate being transparent to visible light and being comprised of a material selected from glass and plastic.

5. The photovoltaic cell of claim 1, wherein an orientation of crystal grain boundaries in each of the silicon layers is approximately perpendicular to major surfaces of the substrate.

6. The photovoltaic cell of claim 1, wherein charge carriers within the silicon layers travel in a direction approximately parallel to crystal grain boundaries.

7. The photovoltaic cell of claim 1, wherein the p-type silicon layer is doped with boron to a concentration of at least 5×10²⁰ cm³.

8. The photovoltaic cell of claim 1, further comprising a top electrode arrangement arranged on the p-type silicon layer, wherein when a total thickness of the n-type silicon, the intrinsic silicon and the p-type silicon layers is less than is needed to fully absorb an incident radiation, the top electrode arrangement is designed to redirect light that has transmitted through the intrinsic silicon layer and the p-type silicon layer back into the intrinsic silicon layer for re-absorption by either designing the top electrode arrangement to be composed of a non-transparent top electrode that is comprised of a material having a reflectivity of incident radiation of at least 50% at an interface between p-type silicon and the top electrode, or by designing the top electrode arrangement to include a top electrode comprised of a transparent conductive material and a reflective layer arranged on the top electrode having a reflectivity of at least 90%.

9. The photovoltaic solar cell of claim 1, wherein each of the intrinsic, n-type and p-type silicon layers are patterned, wherein the annealing occurs after the intrinsic, n-type silicon and p-type silicon layers have been patterned.

10. The photovoltaic cell of claim 1, further comprising a top electrode layer arranged on the p-type silicon layer.

11. A heterojunction solar cell, comprising:
a substrate;
a SnO₂ layer arranged on the substrate;
an intrinsic polycrystalline silicon layer arranged on the SnO₂ layer; and
a p-type polycrystalline silicon layer arranged on the intrinsic silicon layer, the p-type silicon layer being doped with boron to a concentration of at least 10²⁰ cm⁻³, wherein the heterojunction solar cell is produced by crystallizing a combination of the intrinsic silicon layer and the p-type silicon layer by annealing at an elevated temperature, wherein the crystallization being initiated within the p-type silicon layer and then propagating throughout the intrinsic silicon layer, said p-type silicon layer being spaced apart from each of the SnO₂ layer and the substrate by the intrinsic silicon layer.

12. The heterojunction solar cell of claim 11, further comprising a top electrode arranged on the p-type silicon layer, wherein when a total thickness of the intrinsic silicon and the p-type silicon layers is less than is needed to fully absorb an incident radiation, the top electrode arrangement is designed to redirect light that has transmitted through the intrinsic silicon layer and the p-type silicon layer back into the intrinsic silicon layer for re-absorption by either designing the top electrode arrangement to be composed of a non-transparent top electrode that is comprised of a material having a reflectivity of incident radiation of at least 50% at an interface between p-type silicon and the top electrode, or by designing the top electrode arrangement to include a top electrode comprised of a transparent conductive material and a reflective layer arranged on the top electrode having a reflectivity of at least 90%.

13. The heterojunction solar cell of claim 11, wherein a thickness of the intrinsic silicon layer is in the range of 0.5 to 3 μm.

14. The heterojunction solar cell of claim 11, the substrate being transparent to visible light and being comprised of a material selected from glass and plastic.

15. The heterojunction solar cell of claim 11, wherein an orientation direction of crystal grain boundaries of each of the silicon layers is approximately perpendicular to major surfaces of the substrate.

16. The heterojunction solar cell of claim 11, wherein charge carriers within the silicon layers travel in a direction essentially parallel to the crystal grain boundaries.

17. The heterojunction solar cell of claim 11, wherein the p-type silicon layer is doped with boron to a concentration of at least 5×10²⁰ cm³.

18. The heterojunction solar cell of claim 11, wherein each of the intrinsic and p-type silicon layers are patterned, wherein the annealing occurs after the intrinsic and p-type silicon layers have been patterned.

19. A Schottky barrier solar cell, comprising:
a substrate;
a Schottky barrier layer arranged on the substrate;
an intrinsic silicon layer arranged on the Schottky barrier layer; and
a p-type silicon layer arranged on the intrinsic silicon layer, the p-type silicon layer being doped with boron to a concentration of at least 10²⁰ cm³, wherein the Schottky barrier solar cell is produced by crystallizing a combination of the intrinsic silicon layer and the p-type silicon layer in a single annealing process at an elevated temperature, wherein the crystallization being initiated within the p-type silicon layer and progressing into the intrinsic silicon layer, the p-type silicon layer being spaced apart from each of the Schottky barrier layer and the substrate by the intrinsic silicon layer.

20. The Schottky barrier solar cell of claim 19, wherein the elevated annealing temperature is in the range of 650 to 710° C.

21. The Schottky barrier solar cell of claim 19, wherein a thickness of the intrinsic silicon layer being in the range of 0.5 to 3 μm.

22. The Schottky barrier solar cell of claim 19, the substrate being transparent to visible light and being comprised of a material selected from glass and plastic, the annealing having a temperature and duration that does not warp the substrate.

23. The Schottky barrier solar cell of claim 19, wherein an orientation of crystal grain boundaries for each of the silicon layers is approximately perpendicular to major surfaces of the substrate.
